(19) United States
(12) Patent Application Publication
(10) Pub. No.: US 2008/0220164 A1
(43) Pub. Date: Sep. 11, 2008

(54) Feed device for a precursor

(75) Inventors: Hartmut Bauch, Weilrod (DE); Todd Gudgel, Morton Grove, IL (US)

Correspondence Address: DeMont & Breyer, LLC, 100 Commons Way, Ste. 250, Holmdel, NJ, 07733, US

(73) Assignee: SCHOTT AG, Mainz (DE)

(21) Appl. No.: 12/042,827

(22) Filed: Mar. 5, 2008

(30) Foreign Application Priority Data
Mar. 8, 2007 (DE) 10 2007 011 589.1

(51) Int. Cl. C23C 16/44; C23C 16/54

(52) U.S. Cl. 427/248.1; 118/726

(57) ABSTRACT

In order to allow feeding for supply of a gaseous precursor for further processing while avoiding condensation, and in order to allow the feed process to be carried out as simply and reliably as possible, the invention provides a feed method as well as a feed device (1), comprising a vacuum pump (2) for evacuation of a storage vessel (3) for a precursor which is solid and/or liquid at room temperature and atmospheric pressure and for feeding the gaseous precursor which has been vaporized by evacuation, a first line section (23) on the inlet side of the vacuum pump (2) in order to produce a connection between the vacuum pump (2) and the storage vessel (3) for the solid and/or liquid precursor, at least one second line section (24) for supplying carrier gas to the vacuum pump (2), and a monitoring device (5) which can be connected to the first and the second line section (24) and, during operation of the apparatus, provides open-loop and/or closed-loop control for the flow rate of the gaseous precursor and/or of the carrier gas, by keeping the partial pressure of the gaseous precursor below its saturation vapor pressure at least after it enters the pump.

The invention relates in general to a feed device for supplying a gaseous precursor for further processing, and to a method for feeding a gaseous precursor, as claimed in the preambles of the independent claims. The invention relates specifically to a precursor being fed in a carrier gas stream.

For the purposes of the present application, the expression “precursor” is used for the initial material for a coating to be formed during the further processing of the precursor. The expression “precursor” in this case denotes the precursor or precursors for any compound or compounds which forms or form the coating. A precursor may accordingly comprise one or more substances.

In principle, vacuum pumps can be used for feeding and if appropriate also for metering of a precursor which, in the conditions prevailing at the input to further processing—for example at the input to a CVD coating installation, has a vapor pressure which is lower than the pressure at this input and/or the pressure in a process gas stream. However, there is a risk of the saturation vapor pressure being reached when the precursor is fed through the vacuum pump, and of the precursor condensing in the pump.

On the one hand, this may have a negative influence on the performance of the pump. On the other hand, particularly for coating processes such as chemical vapor deposition (CVD), combustion chemical vapor deposition (CCVD), in particular flame pyrolysis, plasma enhanced chemical vapor deposition (PECVD) and plasma impulse chemical vapor deposition (PICVD), it is important to supply an exclusively gaseous precursor in order to allow the coating process to be carried out reliably.

For precursors which are in a solid or liquid form at room temperature and at atmospheric pressure, particularly for applications in coating processes, it is therefore first of all necessary to vaporize the precursor, and then to reliably feed and if required meter the gaseous precursor.

One object of the invention is therefore to provide a capability for feeding for supplying a gaseous precursor for further processing, in particular to a CVD coating installation, in which the precursor is reliably prevented from condensing while being fed and metered. A further object of the invention is to allow the feed process to be carried out in as simple a manner as possible, and as reliably as possible.

According to the invention, these objects are achieved by an apparatus and a method having the features of the independent claims. Advantageous developments are the subject matter of the respectively associated dependent claims.

The invention provides a feed device for supplying a gaseous precursor for further processing, which comprises a vacuum pump for evacuation of a storage vessel for a precursor which is solid and/or liquid at room temperature and atmospheric pressure and for feeding the gaseous precursor which has been vaporized by evacuation, a first line section on the inlet side of the vacuum pump in order to produce a connection between the vacuum pump and the storage vessel for the solid and/or liquid precursor and at least one second line section for supplying carrier gas to the vacuum pump. Furthermore, the feed device has a monitoring device which can be connected to the first and the second line section and, during operation of the apparatus, provides open-loop and/or closed-loop control for the flow rate of the gaseous precursor and/or of the carrier gas, by keeping the partial pressure of the gaseous precursor below its saturation vapor pressure at least after it enters the pump.

For the purposes of the present application, feeding of the precursor can advantageously include metering of the precursor. The feed device then acts as a metering device at the same time. However, the precursor need not necessarily be metered by the feed process or the feed device.

The expression “evacuation” for the purposes of the present application means material being pumped out with its pressure being reduced to a value below the ambient pressure.

The expression “flow rate” on the one hand includes the mass flow, and on the other hand the volume flow, of the relevant substance.

The expression “vacuum pump” is used in general to refer to an appliance which reduces the density and therefore the pressure of the gases contained in a closed area, and which is therefore used to produce, improve and/or maintain a pressure below the ambient pressure.

The relationships between the partial pressure of the precursor and the flow rates of the carrier gas and of the precursor can be described, for example, with respect to the total pressure and the saturation vapor pressure of the precursor. In this case, the partial pressure of the precursor corresponds to the molar fraction of the precursor in the gas phase multiplied by the total pressure. Subject to the condition according to the invention that the partial pressure of the precursor must be below its saturation vapor pressure, it is possible to derive, for example, a relationship for the ratio of the saturation vapor pressure of the precursor to the total pressure for the mass flows of the precursor and of the carrier gas, taking into account the respective molar masses.

In one possible embodiment of the invention, the monitoring device may therefore be configured such that, in response to the mass flow of the precursor, it regulates the mass flow of the carrier gas taking into account the total pressure as well as the molar masses of the precursor and the carrier gas, and the saturation vapor pressure of the precursor, such that the partial pressure of the gaseous precursor is kept below its saturation vapor pressure.

Since the invention allows the precursor and the carrier gas to be subjected to open-loop and closed-loop control taking account of the saturation vapor pressure, the invention offers the advantage of simple and reliable matching of the substances in the respectively prevailing operating conditions to one another, without having to record further variables, by means of additional measurement devices. In consequence, the apparatus according to the invention is particularly compact and, furthermore, is advantageously reliable. A precursor which is solid and/or liquid at room temperature is thus supplied by means of the invention in vaporized form for further processing in such a way that condensation of the precursor is reliably prevented.

In one advantageous development of the invention, the monitoring device has a first mass-flow controller (MFC) for the gaseous precursor in the first line section and/or a second mass-flow controller (MFC) for the carrier gas in the second line section. Mass-flow controllers offer a robust solution, which can be used over wide pressure ranges, for closed-loop and/or open-loop control of the flow rate of the precursor and of the carrier gas.

In order to allow the feed device to be handled particularly easily, a further embodiment of the invention provides that the monitoring device has a memory in which at least one saturation vapor pressure of a precursor can be stored, in which case the memory can be connected in particular to the first and/or to the second mass-flow controller. If the feed device is used essentially for the same precursor, the user can store its saturation vapor pressure in the memory so that this value is always available, without any further steps.

In one advantageous development for flexible use of the feed device for different precursors, the invention provides that the monitoring device has a memory in which at least the values of the saturation vapor pressure of each precursor are stored for a plurality of precursors, and an input device which makes it possible for a user to select one precursor for an incipient feed and metering task. In further embodiments of this development, the molar masses, the densities and further suitable variables of precursors and carrier gases can also be stored in the memory.

Particularly when further processing is intended to be carried out at a pressure below the ambient pressure, but the vacuum pump has an output pressure which corresponds to the ambient pressure, the invention advantageously provides a restrictor valve upstream of the inlet to the further processing. For this purpose, the feed device in one appropriate embodiment has a third line section for supplying at least the vaporized precursor for further processing on the outlet side of the vacuum pump, with the third line section having a valve for setting and/or open-loop and/or closed-loop control of the output pressure. The pump is therefore provided with a constant output pressure so that the invention can be used flexibly for different operating parameter requirements.

According to the invention, the output pressure pₒᵤₜ at which the mixture of the gaseous precursor and of the carrier gas leaves the vacuum pump is set and/or subjected to closed-loop and/or open-loop control in one advantageous development.

In order to assist the vaporization of the solid and/or liquid precursor, one advantageous development of the invention provides for the feed device to have a first heating device for heating the first line section, in particular from the storage vessel to the first mass-flow controller. Additionally or alternatively, a second heating device can be provided for heating the first line section from the first mass-flow controller to the inlet to the vacuum pump. It is likewise within the scope of a further embodiment of the invention to provide a third heating device for heating the vacuum pump. Furthermore, additionally or alternatively, the feed device may have a fourth heating device for heating the third line section downstream from the outlet from the vacuum pump. Depending on the point where the greatest risk of condensation occurs in the respective application, the invention offers the capability to flexibly heat-treat the respective line sections and/or the vacuum pump and/or its or their working area such that the process conditions are maintained with a safe margin from the condensation conditions.

In advantageous developments of the invention, the temperature T₁ of the gaseous precursor can therefore be set and/or subjected to open-loop and/or closed-loop control in a line section from the storage vessel to the first mass-flow controller, and/or the temperature T₂ of the gaseous precursor can be set and/or subjected to open-loop and/or closed-loop control in a line section from the first mass-flow controller to the inlet to the vacuum pump, and/or the temperature T₃ of the gaseous precursor and/or of the carrier gas can be set and/or subjected to open-loop and/or closed-loop control in the vacuum pump, and/or the temperature T₄ of the mixture of the gaseous precursor and of the carrier gas can be set and/or subjected to open-loop and/or closed-loop control in a line section after emerging from the vacuum pump.

Depending on the field of application, the invention offers various possible ways to vaporize, to feed and to meter the precursor. By way of example, a multistage vacuum pump may be used. In particular, the vacuum pump may be selected from the group which comprises membrane pumps, turbopumps, scroll pumps and rotary-slide pumps. In the case of a multistage pump, one advantageous development of the invention provides for the carrier gas to be added at the last stage of the vacuum pump, that is to say as late as possible, because the risk of condensation increases as the compression increases.

The invention furthermore provides a method for feeding and metering a gaseous precursor for further processing, having the following steps:
a) provision of a precursor which is solid and/or liquid at room temperature and atmospheric pressure,
b) vaporization of the solid and/or liquid precursor at least by reducing the pressure over the solid and/or liquid precursor in order to produce a gaseous precursor, using a vacuum pump,
c) mixing of the gaseous precursor with a carrier gas in the vacuum pump,
   in which the flow rates of the gaseous precursor and of the carrier gas are matched to one another such that the partial pressure of the gaseous precursor is kept below its saturation vapor pressure, at least after it enters the vacuum pump.

In the same way as the apparatus according to the invention, the method according to the invention can likewise advantageously be used to process a multiplicity of precursor substances. For example, according to the invention, the precursor is selected from the group which comprises TiCl₄, SnCl₄, NbCl₅, TaCl₅, AlCl₃, SiCl₄, hexamethyldisiloxane (HMDSO), hexamethyldisilazane (HMDSN), tetramethyldisiloxane (TMDSO) and tetraoxysilane (tetraethyl orthosilicate, TEOS).

In order to allow particularly user-friendly and reliable handling of the method, even when the invention is used for a multiplicity of different precursors, one development of the invention provides that at least the values of the saturation vapor pressure of each precursor are stored for a plurality of precursors, and are made available for closed-loop and/or open-loop control of the rates of the gaseous precursor and of the carrier gas in response to the selection of one precursor for an incipient feed and metering task by a user.

The invention also provides for the use of an apparatus as described above and of a method as described above for feeding and metering a precursor which is solid and/or liquid at room temperature and atmospheric pressure, for further processing in a coating process. In this case, the coating process may, for example, be selected from the group which comprises chemical vapor deposition (CVD), combustion chemical vapor deposition (CCVD), in particular flame pyrolysis, plasma enhanced chemical vapor deposition (PECVD) and plasma impulse chemical vapor deposition (PICVD).

In this case, the invention offers the advantage that precursors which are solid and/or liquid at room temperature and at atmospheric pressure need not be metered in a gaseous form but in a liquid form without the simultaneous vaporization, feeding and metering according to the invention. Particularly for precursors which are solid at room temperature and atmospheric pressure, this means the use of a solvent. However, the use of a solvent as a further substance in the process could actually sensitively interfere with the conduct of a coating process for the methods mentioned above.

The invention will be explained in more detail in the following text using exemplary embodiments and with reference to the attached drawings. The same components are provided with the same reference symbols in all the figures. In the figures:

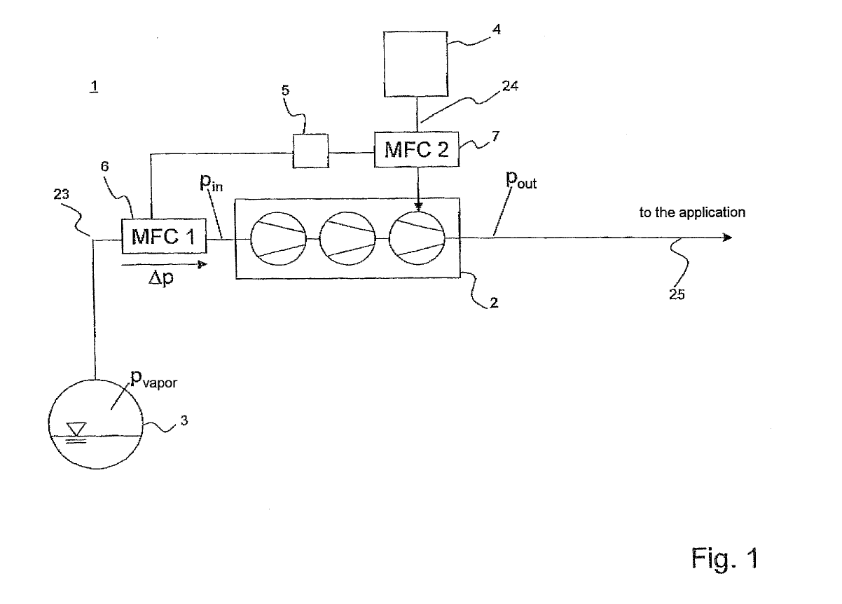

FIG. 1 shows a schematic illustration of a feed device according to a first embodiment of the invention,

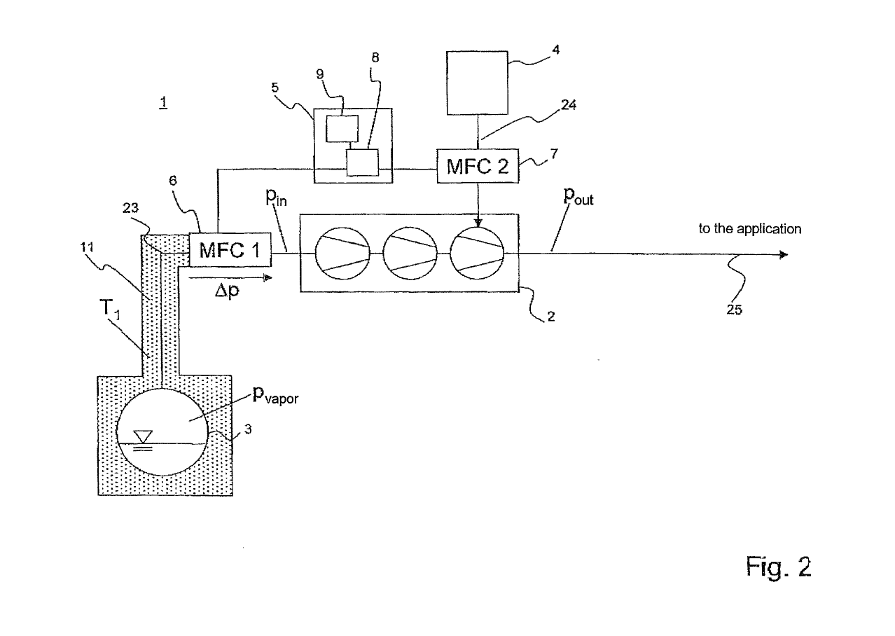

FIG. 2 shows a schematic illustration of a feed device according to a second embodiment of the invention,

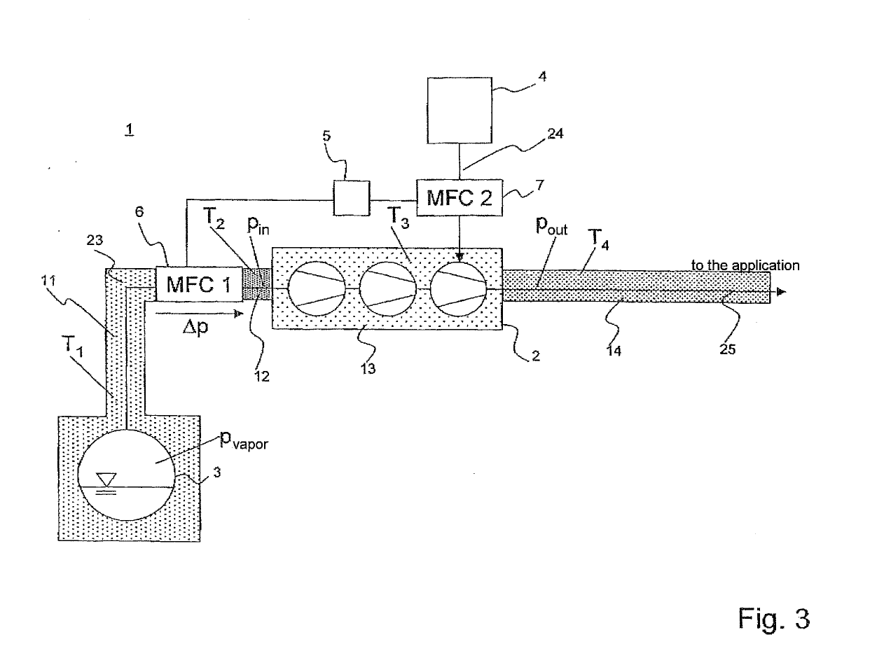

FIG. 3 shows a schematic illustration of a feed device according to a third embodiment of the invention, and

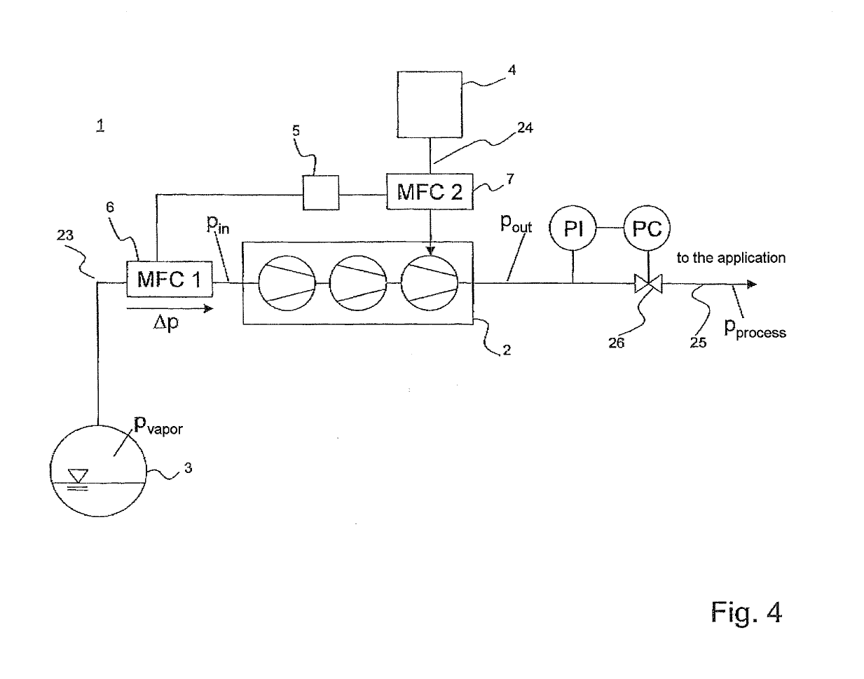

FIG. 4 shows a schematic illustration of a feed device according to a fourth embodiment of the invention.

The feed device 1 according to a first embodiment of the invention, as illustrated schematically in FIG. 1, has a storage vessel 3 in which a precursor is stored. The precursor is provided in solid and/or liquid form. A first line section 23 connects the storage vessel 3 to a vacuum pump 2, so that the vacuum pump can evacuate the storage vessel 3 via the line section 23, in order to vaporize the precursor. The precursor enters the vacuum pump 2 in gaseous form at a pressure pᵢₙ.

The illustrated exemplary embodiments use a three-stage vacuum pump 2. However, single-stage or other multistage vacuum pumps can also be used within the scope of the invention. In particular, the invention does not preclude a plurality of vacuum pumps being connected in series. If required, oil-free vacuum pumps may be used in order to avoid oil contamination of the precursor and/or of the carrier gas.

A carrier gas is admixed with the precursor in the vacuum pump 2. The carrier gas is kept in a storage vessel 4. The vacuum pump compresses the precursor or the mixture of the precursor and the carrier gas to a pressure of pₒᵤₜ>pᵢₙ at which the mixture is passed through a third line section 25 to the application, that is to say for further processing of the precursor or of the mixture of the precursor and of the carrier gas.

The flow rates of the precursor and carrier gas which are supplied from the respective storage containers 3, 4 to the vacuum pump 2 are matched to one another such that condensation of the precursor is avoided, at least in the vacuum pump 2. A monitoring device 5 is provided for this purpose and is connected to a first mass-flow controller (MFC1) 6 and to a second mass-flow controller (MFC2) 7. Wire-based or wire-free connections may be used for the connection between the monitoring device 5 and the mass-flow controllers 6, 7.

If, for example, the mass flow of the precursor is fixed in accordance with an appropriate requirement by means of the first mass-flow controller 6, the monitoring device 5 causes the second mass-flow controller 7 to fix the mass flow of the carrier gas such that the partial pressure of the precursor in the mixture of carrier gas and precursor remains below the saturation vapor pressure of the precursor.

In this case, the expression “fixing” means setting, open-loop or closed-loop control, depending on how the monitoring device 5 is designed. For example, for a refinement as a control device, the monitoring device 5 may have measurement devices, which are not illustrated in the figures, for the mass flows of the precursor and/or of the mixture of the precursor and carrier gas, and/or for the total pressure in the mixture of the precursor and carrier gas.

When designing a feed device 1 such as this, care should be taken to ensure in particular that the first mass-flow controller 6 has a pressure loss Δp (Delta p). The vacuum pump 2 itself has a specific minimum input pressure pᵢₙ. These two variables determine which precursors can be supplied by the feed device for further processing, because the vapor pressure pᵥₐₚₒᵣ of the precursor must be at least as great as the sum of pᵢₙ and Δp.

In a further embodiment, which is illustrated schematically in FIG. 2, the feed device 1 has a monitoring device 5 which has a memory 8. The memory 8 has a plurality of memory locations in which at least values for the respective saturation vapor pressure of a plurality of precursor substances are stored. Furthermore, for example, values for the molar masses of the plurality of precursor substances may also be stored in the memory 8.

The memory 8 is connected to an input device 9. A user can use the input device 9 to select a precursor which is intended to be used for the proposed application. In response to this selection, the monitoring device 5 uses the memory 8 to access the value of the saturation vapor pressure of this particular precursor. Depending on how the monitoring device 5 is configured, the monitoring device can also access the value for the molar mass of the precursor. Using these values from the memory 8, the mass flows of the precursor and of the carrier gas are then set and/or subjected to open-loop and/or closed-loop control by means of the monitoring device 5, via the mass-flow controllers 6, 7, such that the partial pressure of the precursor is kept below its saturation vapor pressure.

In addition, the feed device 1 has a first heating device 11 by means of which the storage vessel 3 for the precursor and a part of the first line section 23, specifically the part from the storage vessel 3 for the precursor to the first mass-flow controller 6, can be heated to a temperature T₁.

In a further embodiment, which is illustrated schematically in FIG. 3, the feed device 1 additionally has a second heating device 12 by means of which the part of the first line section 23 from the first mass-flow controller 6 to the inlet to the vacuum pump 2 can be heated to a temperature T₂. The vacuum pump 2 can be heated to a temperature T₃ by means of a third heating device 13. In particular, the heating device 13 may be designed such that essentially only the working area of the vacuum pump 2 is heated to the temperature T₃, and the other components of the vacuum pump 2 remain unheated. Furthermore, the feed device 1 has a fourth heating device 14 by means of which the third line section 25 from the output of the vacuum pump 2 to the application, that is to say the further processing, can be heated to a temperature T₄.

In a further embodiment of the invention, which is illustrated schematically in FIG. 4, the feed device 1 has a restrictor valve 26 in the third line section 25 downstream from the output from the vacuum pump 2. In the illustrated development, the restrictor valve can be controlled by a pressure controller PC. The pressure controller PC is connected to a pressure sensor PI, which measures the actual value of the pressure pₒᵤₜ. If the process pressure p_{process} is less than the output pressure pₒᵤₜ from the vacuum pump, the pressure controller PC controls the valve 26, in response to the actual value pₒᵤₜ, in order to set the pressure p_{process}. Virtually any desired vacuum pump whose output pressure is equal to the atmospheric pressure can therefore also be used for applications involving a reduced pressure, because the restriction control system offers the pump a constant output pressure.

It is obvious to a person skilled in the art that the invention is not restricted to the exemplary embodiments described above but in fact can be varied in many ways. In particular, the features of the individual exemplary embodiments can also be combined with one another or interchanged with one another.

### LIST OF REFERENCE SYMBOLS

1 Feed and metering device
2 Vacuum pump
23 First line section
24 Second line section
25 Third line section
26 Valve
3 Storage vessel for a precursor
4 Storage vessel for carrier gas
5 Monitoring device
6 First mass-flow controller
7 Second mass-flow controller
8 Memory
9 Input device
11 First heating device
12 Second heating device
13 Third heating device
14 Fourth heating device

1. A feed device (1) for supplying a gaseous precursor for further processing, comprising
a vacuum pump (2) for evacuation of a storage vessel (3) for a precursor which is solid and/or liquid at room temperature and atmospheric pressure and for feeding the gaseous precursor which has been vaporized by evacuation,
a first line section (23) on the inlet side of the vacuum pump (2) in order to produce a connection between the vacuum pump (2) and the storage vessel (3) for the solid and/or liquid precursor,
at least one second line section (24) for supplying carrier gas to the vacuum pump (2), and
a monitoring device (5) which is connected to at least one of the first and the second line section (23, 24) and, during operation of the feed device (1), provides open-loop and/or closed-loop control for the flow rate of the gaseous precursor and/or of the carrier gas, by keeping the partial pressure of the gaseous precursor below its saturation vapor pressure at least after it enters the pump.

2. The feed device (1) as claimed in claim 1,
wherein
the monitoring device (5) has a first mass-flow controller (6) for the gaseous precursor in the first line section (23) and/or a second mass-flow controller (7) for the carrier gas in the second line section (24).

3. The feed device as claimed in claim 1,
wherein
the monitoring device (5) has a memory (8) in which at least one saturation vapor pressure of a precursor is stored.

4. The feed device (1) as claimed in claim 1,
wherein the monitoring device (5) has a memory (8) in which the values of the saturation vapor pressure of each precursor are stored for a plurality of precursors, and an input device (9) which makes it possible for a user to select one precursor for an incipient feed and metering task.

5. The feed device (1) as claimed in claim 1,
further comprising
a third line section (25) for supplying the vaporized precursor for further processing on the outlet side of the vacuum pump (2), which third line section (25) has a valve (26) for setting and/or open-loop and/or closed-loop control of the output pressure.

6. The feed device (1) as claimed in claim 1,
further comprising
a first heating device (11) for heating the first line section (23) from the storage vessel (3) to the first mass-flow controller (6).

7. The feed device (1) as claimed in claim 1,
further comprising
a second heating device (12) for heating the first line section (23) from the first mass-flow controller (6) to the inlet to the vacuum pump (2).

8. The feed device (1) as claimed in claim 1,
further comprising
a third heating device (13) for heating the vacuum pump (2).

9. The feed device (1) as claimed in claim 1,
further comprising
a fourth heating device (14) for heating the third line section (25).

10. The feed device (1) as claimed in claim 1,
wherein
the vacuum pump (2) is a multistage vacuum pump (2).

11. The feed device (1) as claimed in claim 1,
wherein
the vacuum pump (2) is selected from the group consisting of membrane pumps, turbopumps, scroll pumps and rotary-slide pumps.

12. A method for feeding a gaseous precursor for further processing, comprising:
a) providing a precursor which is solid and/or liquid at room temperature and atmospheric pressure,
b) vaporizing the solid and/or liquid precursor at least by reducing the pressure over the solid and/or liquid precursor in order to produce a gaseous precursor, using a vacuum pump (2), and
c) mixing the gaseous precursor with a carrier gas in the vacuum pump (2),
in which
the flow rates of the gaseous precursor and of the carrier gas are matched to one another such that the partial pressure of the gaseous precursor is kept below its saturation vapor pressure, at least after it enters the vacuum pump (2).

13. The method as claimed in claim 12,
wherein
the precursor is selected from the group consisting of TiCl₄, SnCl₄, NbCl₅, TaCl₅, AlCl₃, SiCl₄, hexamethyldisiloxane (HMDSO), hexamethyldisilazane (HMDSN), tetramethyldisiloxane (TMDSO) and tetraoxysilane (tetraethyl orthosilicate, TEOS).

14. The method as claimed in claim 12,
wherein
the values of the saturation vapor pressure of each precursor are stored for a plurality of precursors, and are made available for closed-loop and/or open-loop control of the flow rates of the gaseous precursor and of the carrier gas in response to the selection of one precursor for an incipient feed and/or metering task by a user.

15. The method as claimed in claim 12,
wherein
the output pressure pₒᵤₜ at which the mixture of the gaseous precursor and of the carrier gas leaves the vacuum pump (2) is set and/or subjected to closed-loop and/or open-loop control.

16. The method as claimed in claim 12,
wherein
the temperature T₁ of the gaseous precursor is set and/or subjected to open-loop and/or closed-loop control at least in the part of a first line section (23) from a storage vessel (3) to a first mass-flow controller (6).

17. The method as claimed in claim 12,
wherein
the temperature T₂ of the gaseous precursor is set and/or subjected to open-loop and/or closed-loop control at least in the part of a first line section (23) from a first mass-flow controller (6) to the inlet to the vacuum pump (2).

18. The method as claimed in claim 12,
wherein
the temperature T₃ of the gaseous precursor and/or of the carrier gas is set and/or subjected to open-loop and/or closed-loop control in the vacuum pump (2).

19. The method as claimed in claim 12,
wherein
the temperature T₄ of the mixture of the gaseous precursor and of the carrier gas is set and/or subjected to open-loop and/or closed-loop control at least in a part of a third line section (25) after emerging from the vacuum pump (2).

20. A method for feeding and/or metering a precursor which is solid and/or liquid at room temperature and atmospheric pressure, for further processing in a coating process, the method comprising utilizing the apparatus as claimed in claim 1.

21. A method for feeding and/or metering a precursor which is solid and/or liquid at room temperature and atmospheric pressure, for further processing in a coating process, the method comprising utilizing the method as claimed in claim 12.

22. The method as claimed in claim 21,
wherein
the coating process is selected from the group consisting of:
chemical vapor deposition (CVD),
combustion chemical vapor deposition (CCVD),
plasma enhanced chemical vapor deposition (PECVD)
and
plasma impulse chemical vapor deposition (PICVD).
